(19) United States
(12) Patent Application Publication
(10) Pub. No.: US 2022/0415727 A1
(43) Pub. Date: Dec. 29, 2022

(54) APPARATUS AND METHOD FOR SETTING A PRECISE VOLTAGE ON TEST CIRCUITS

(71) Applicant: IC ANALYTICA, LLC, Austin, TX (US)

(72) Inventors: Joseph S. SPECTOR, Austin, TX (US); Richard WUNDERLICH, Austin, TX (US); Patrick G. DRENNAN, Gilbert, AZ (US)

(21) Appl. No.: 17/848,954

(22) Filed: Jun. 24, 2022

Related U.S. Application Data
(60) Provisional application No. 63/215,050, filed on Jun. 25, 2021.

(51) Int. Cl. H01L 21/66; G01R 31/28

(52) U.S. Cl. CPC H01L 22/34; G01R 31/2884

(57) ABSTRACT

An apparatus has a semiconductor wafer hosting rows and columns of chips, where the rows and columns of chips are separated by scribe lines. Selection circuitry is positioned within the scribe lines. The selection circuitry is connected to test circuits in the scribe lines. The selection circuitry operates to enable voltage control at a single test circuit while disabling all other test circuits.

### CROSS-REFERENCE TO RELATED INVENTION

This application claims priority to U.S. Provisional Patent Application Ser. No. 63/215,050, filed Jun. 25, 2021, the contents of which are incorporated herein by reference.

### FIELD OF THE INVENTION

This invention relates generally to testing semiconductor wafers. More particularly, this invention relates to setting a precise voltage on test circuits.

### BACKGROUND OF THE INVENTION

FIG. 1 illustrates a known semiconductor wafer testing system including test equipment 100 connected to a probe card 102, which makes connections with pads on a wafer 104. FIG. 2 illustrates a semiconductor wafer 104 with individual chips 200. The individual chips 200 form rows and columns of chips which are separated by scribe lines 202. Within scribe line 202 there are test circuits 204. The test circuits 204 are used during wafer level testing. When testing is completed, a saw is used in the scribe lines to divide the individual chips for subsequent packaging. This cutting process destroys the test circuits 204 in the scribe lines. FIG. 3 illustrates a simple test circuit with a gate pad 300, a source pad 302 and a drain pad 304. A probe card needle 306 is connected to the drain pad 304.

FIG. 4 illustrates test equipment 100 comprising Source Measurement Units SMU1 and SMU2. The SMU voltages are connected through wire connections from equipment cables, probe tips, probe pads, and on-chip metal routes to the intended circuit, shown here as a resistor R9. It should be appreciated that the test circuit may be of arbitrary complexity.

Current runs from the SMU to the test circuit, which means the voltage at resistor R9 will be degraded from the SMU voltages. The resistances R1-R8 are not well controlled.

Resistances R1, R2, R3, R4, R5, and R6 represent parasitic resistances in the cables, probe card, probe tips and/or probe pads. Resistances R7 and R8 represent parasitic resistances from the on-chip wire routes.

Each SMU contains two connections, a “force” connection and a “sense” connection. In this case, a target voltage is applied through the force terminal of the SMU. The current from the force terminal flows through R1 which creates a voltage drop (known as a “IR voltage” drop) which is equal to the resistance of R1 times the value of the current. Due to the IR voltage drop, the voltage at node N1 is different from the voltage that is applied in the SMU. The sense terminal of the SMU measures the voltage. The current through the sense terminal is designed to be very low so that there is negligible IR voltage drop through R2. The SMU compares the sense voltage to the intended target voltage and increases the force voltage so that the target voltage is obtained at the “Kelvin node”, N1. The Kelvin nodes, N1 and N2 where the force and sense terminals meet, may be typically located at the cable junctions or at the probe card or at the probe pad or on the chip 104.

FIG. 5 illustrates a prior art system with test equipment 100 and a wafer 104 with multiple test circuits 1 through N. All of the test circuits in the array share a common Vdd and/or Vss pad for efficient pad utilization. Each test circuit is digitally addressable such that only one circuit is enabled, and the remaining circuits are disabled. The current draw from the common Vdd and Vss pads is several orders of magnitude higher for the enabled circuit as compared to any of the disabled circuits. This means that the current measured at the SMU is approximately the same as the current draw for the enabled circuit. This has two problems.

First, if the array of test circuits is large, the leakage current from the disabled circuits can be large enough to cause a significant error in the current measurement for the enabled circuit. Second, it is desirable to measure the leakage current on each individual test circuit. In this case, all circuits are disabled, and the current measurement is the combine leakage for all of the test circuits. There is no ability to measure the leakage current on each test circuit.

Thus, there is a need for improved power management of test circuits in wafer scribe lines.

### SUMMARY OF THE INVENTION

An apparatus has a semiconductor wafer hosting rows and columns of chips, where the rows and columns of chips are separated by scribe lines. Selection circuitry is positioned within the scribe lines. The selection circuitry is connected to test circuits in the scribe lines. The selection circuitry operates to enable voltage control at a single test circuit while disabling all other test circuits.

### BRIEF DESCRIPTION OF THE FIGURES

The invention is more fully appreciated in connection with the following detailed description taken in conjunction with the accompanying drawings,0 in which:

FIG. 1 illustrates a semiconductor wafer testing system known in the prior art.

FIG. 2 illustrates a prior art semiconductor wafer with a scribe line hosting test circuits.

FIG. 3 illustrates a prior art test circuit and associated probe card needle.

FIG. 4 illustrates a prior art resistance network associated with a test circuit.

FIG. 5 illustrates prior art test equipment and test circuits on a wafer.

FIG. 6 illustrates a wafer with test circuit selection circuitry in accordance with an embodiment of the invention.

FIG. 7 illustrates a wafer with header switch selection circuitry in accordance with an embodiment of the invention.

FIG. 8 illustrates a wafer with footer switch selection circuitry in accordance with an embodiment of the invention.

FIG. 9 illustrates selection circuitry utilized in accordance with an embodiment of the invention.

FIG. 10 illustrates selection circuitry utilized in accordance with an embodiment of the invention.

FIG. 11 illustrates selection circuitry utilized in accordance with an embodiment of the invention.

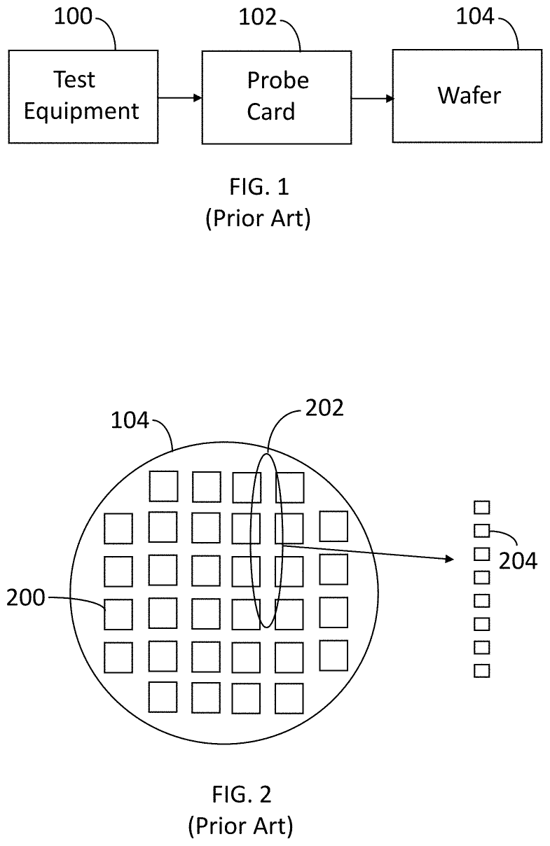

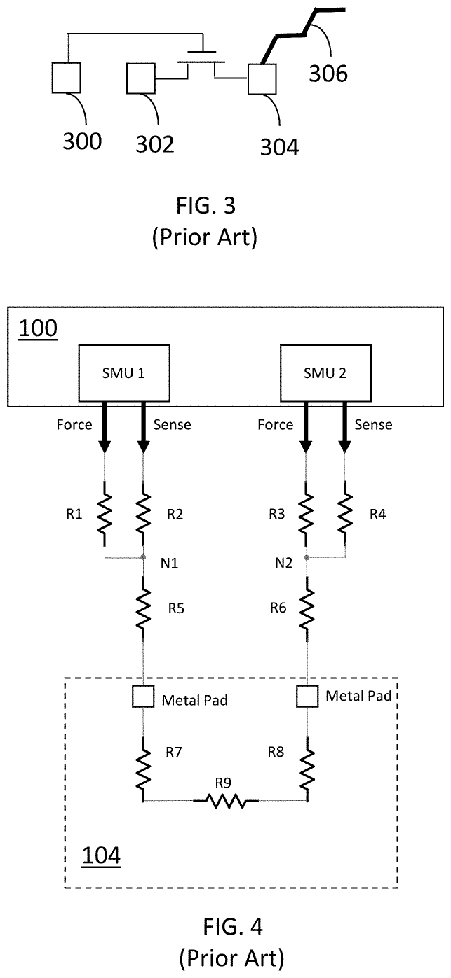

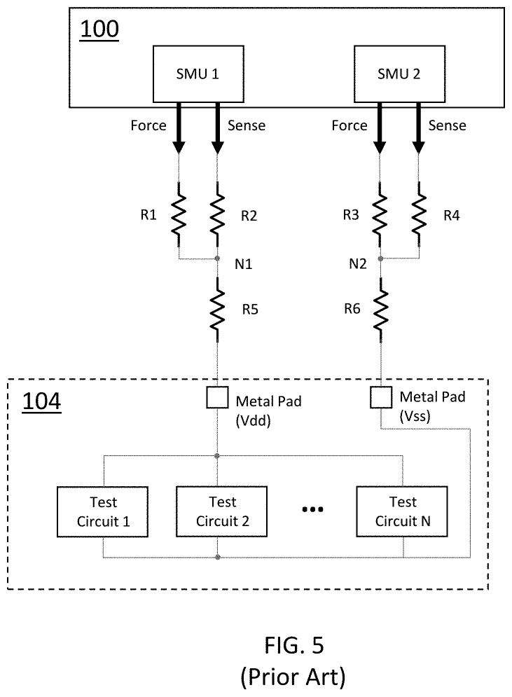

Like reference numerals refer to corresponding parts throughout the several views of the drawings.

### DETAILED DESCRIPTION OF THE INVENTION

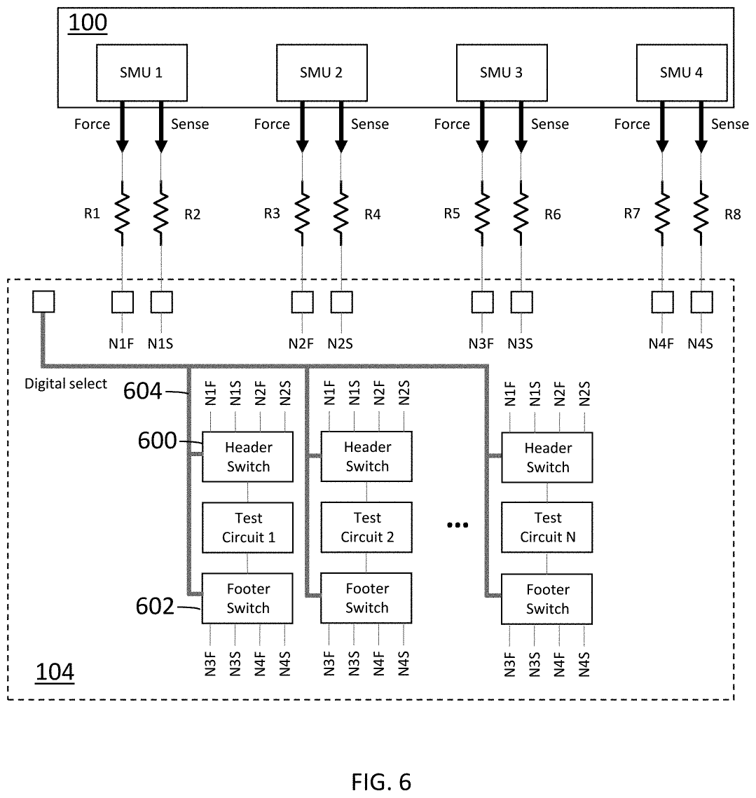

FIG. 6 illustrates a header switch 600 inserted between the SMU supplies and each test circuit. A header switch controls the Vdd supply and a footer switch 602 controls the Vss supply in the case where the test circuit is a digital circuit, such as a ring oscillator.

Each test circuit in the addressable array has its own header switch and its own footer switch. A digital select line 604 is connected from external pad connection(s) to each header switch and footer switch. The digital addressing is such that only one circuit can be selected at a time (a value of “1”). The digital select value for all the remaining test circuits is set to “0”. By way of example the digital select signal may be initiated at test equipment 100 and then be applied to the digital select pad by a probe pin.

The SMU connections for the power supply are common across all header switches and footer switches as shown in the node labeling in the figure. In this example there are four SMUs — SMU1, SMU2, SMU3 and SMU4, each with force and sense lines, respectively N1F, N1S, N2F, N2S, N3F, N3S, N4F and N4S. These force and sense line nodes have connections to the header switch 600 and footer switch 602, as shown in FIG. 6. In this embodiment, the header switches 600 are connected to nodes N1F, N1S, N2F, N2S and the footer switches 602 are connected to nodes N3F, N3S, N4F, NFS.

Using both a header switch and a footer switch allows for the elimination or reduction of the IR voltage drop for both power supply rails.

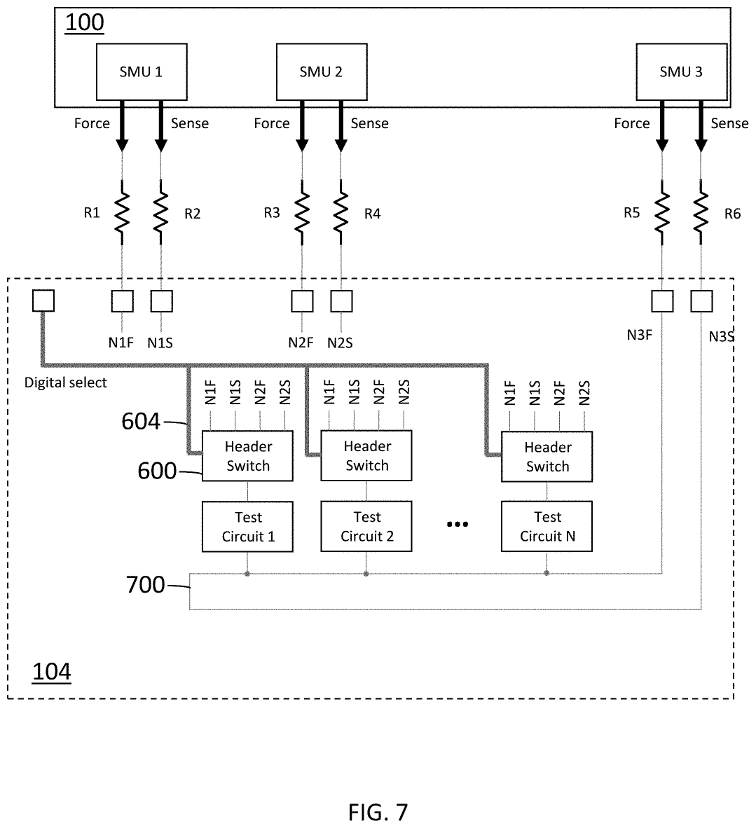

An embodiment of the invention only uses header switches 600, as shown in FIG. 7.

The Kelvin node 700 for the Vss (where the force and sense for SMU3 meet), in this figure, is shown to be on the chip 104. This Kelvin node could occur elsewhere along the SMU supply line (e.g., off-chip). The advantage of the implementation of FIG. 7 is reduced complexity.

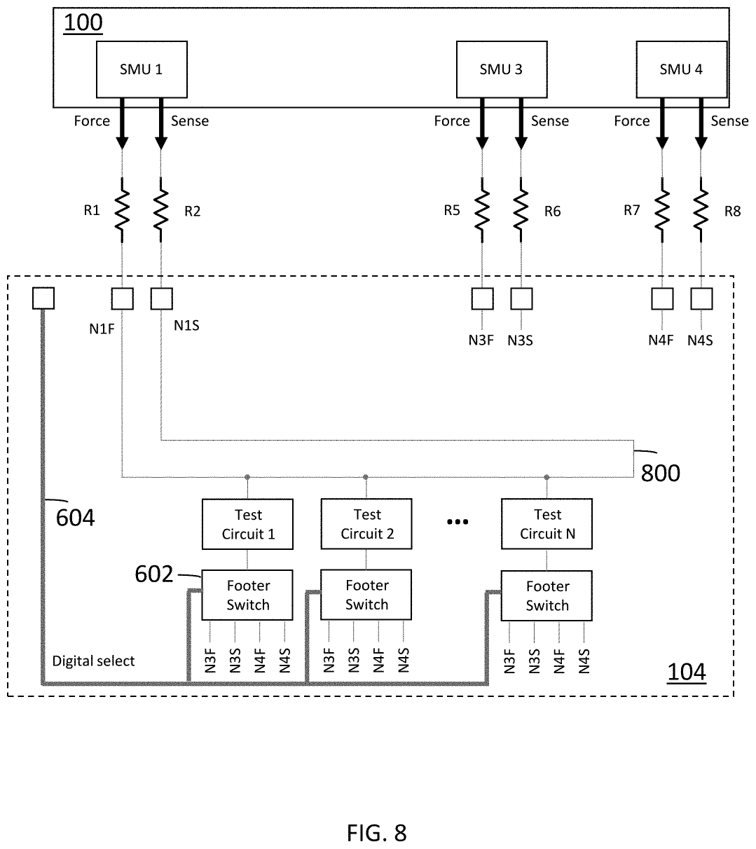

FIG. 8 illustrates an embodiment of the invention that only uses footer switches 602.

The Kelvin node 800 for the Vdd (where the force and sense for SMU1 meet), in this figure, is shown to be on the on the chip. This Kelvin node could occur elsewhere along the SMU supply line (e.g., off-chip). The advantage of this implementation is reduced complexity.

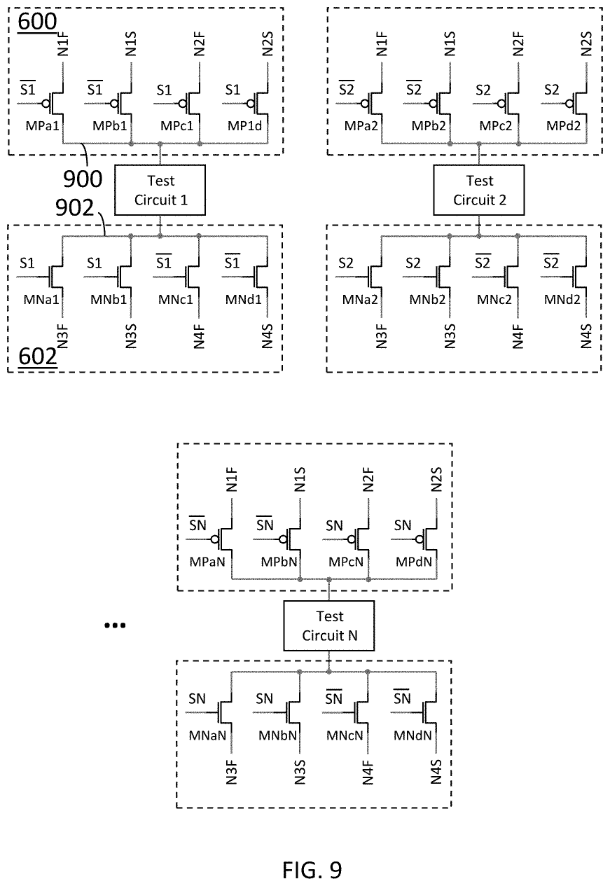

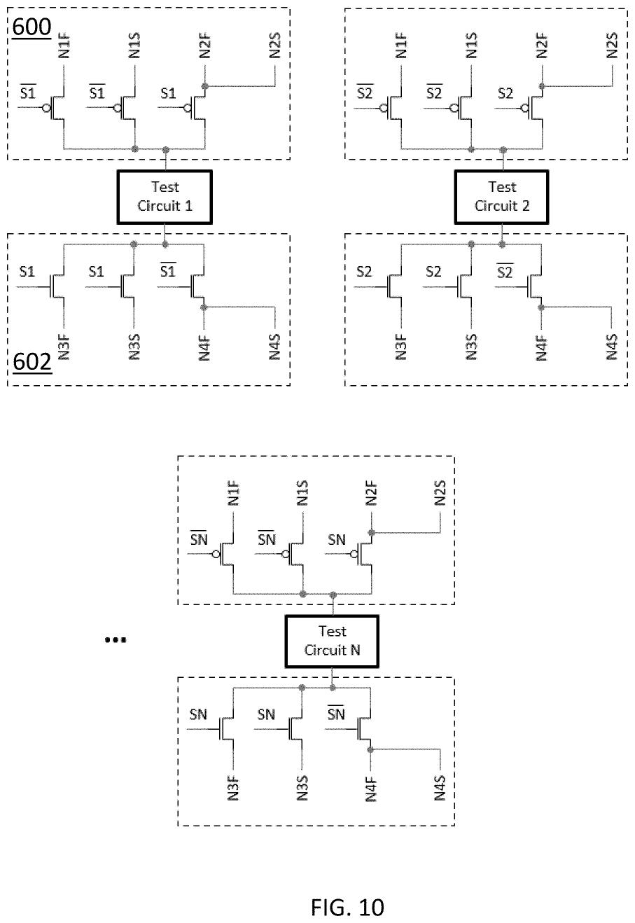

FIG. 9 illustrates an implementation of the header switch 600 and the footer switch 602. The header and footer switch for each test circuit is controlled by digital selection, S1, S2, . . . SN for N instances of test circuits. (The bar over the selection indicates that the selection signal is inverted). For the N instances, only one selection can have a value of “1” at a time and all of the remaining selections are “0”. For example, if S1 has a logical value of “1”, S2-SN selections must be “0”. If S1 is “1”, then transistors MNa1, MNb1, MPa1, MPb1 are turned on, and the power to Test Circuit 1 is connected to the force and sense of SMU1 (nodes N1F, N1S) and to the force and sense of SMU3 (nodes N3F, N3S). The Kelvin node for the force and sense of SMU1 is node 900 and node 902 for SMU3. These nodes are directly adjacent to Test Circuit1 (both physically and schematically). The gates of transistors MNc1, MNd1, MPc1, and MPd1 are disconnected from SMU2 and SMU4 (nodes N2F, N2S, N4F, N4S). Since S2-SN are “0”, all of these test circuits are disconnected from SMU1 and SMU3 but they are connected to SMU2 and SMU4.

The applied voltage on SMU3 is set to be the same as the applied voltage on SMU1 so that there is no voltage drop across the “off” transistors in the header and footer switches. Thus, for the selected transistor, all of the current from the selected test circuit is diverted to SMU1 and SMU3 and all of the current for the unselected test circuits is diverted to SMU2 and SMU4.

FIG. 10 illustrates another implementation of the header switch 600 and footer switch 602, in which the Kelvin node point for the non-selected test circuits is located before the switches. This saves circuit complexity and wire routing complexity.

This implementation may incur a significant IR voltage drop if the leakage current for the non-selected test circuits is large enough (i.e., on the SMU2 and SMU4 legs). If the array of test circuits is large enough, the leakage currents for the non-selected test circuits can add up to be significant. Thus, this implementation has a limitation on the number of test circuits that can be placed in the array.

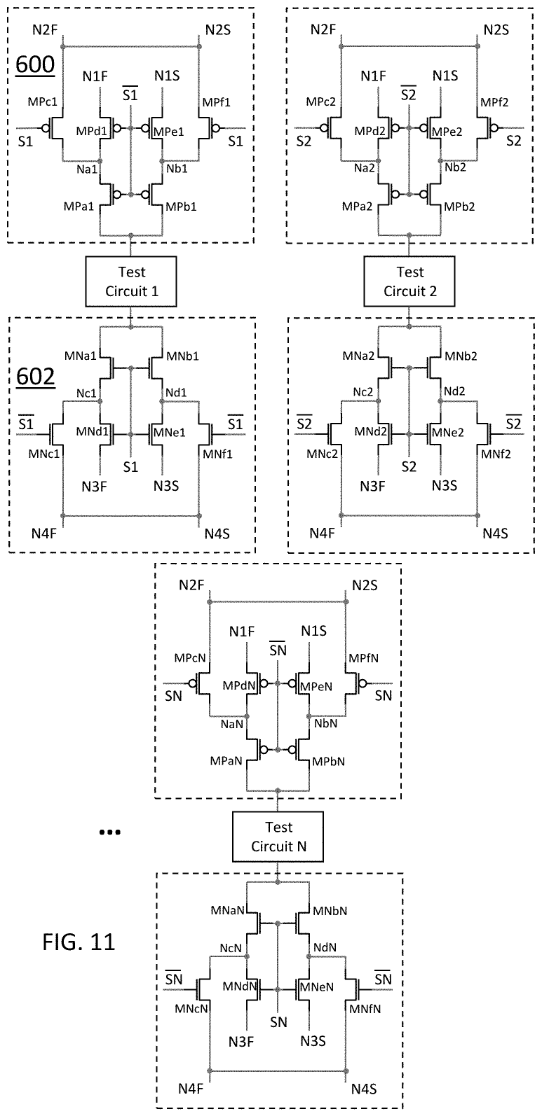

FIG. 11 illustrates another implementation that allows for the Kelvin node of SMU2 and SMU4 (i.e., the connection between force and sense for each SMU) to be placed outside the header and footer switches (e.g., perhaps off-chip). If S1 is set to “1”, S2-SN are set to “0” and transistors MPa1, MPb1, MPd1, MPe1 turn on and connect SMU1 (nodes N1F and N1S) to the top side of Test Circuit 1. Similarly, MNa1, MNb1, MNd1, MNe1 turn on and connect the bottom side of Test Circuit 1 to SMU3. SMU2 and SMU4 are disconnected from Test Circuit 1 because transistors MPc1, MPf1, MNc1 and MNf1 are off.

While S1 is still “1”, the opposite set of transistors are turned on/off in in the header and footer switches of Test Circuit 2 through Test Circuit N. For header switch in Test Circuit 2, SMU2 does not directly connect to the top of the test circuit like it did in the previous circuits. In this case, the SMU 2 connection to node Na2 and Nb2 are isolated from the test circuit by MPa2 and MPb2, which are turned off.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
a semiconductor wafer hosting rows and columns of chips, where the rows and columns of chips are separated by scribe lines; and
selection circuitry positioned within the scribe lines, the selection circuitry connected to test circuits in the scribe lines, the selection circuitry operating to enable voltage control at a single test circuit while disabling all other test circuits.

2. The apparatus of claim 1 wherein the selection circuitry includes a header switch for each test circuit.

3. The apparatus of claim 1 wherein the selection circuitry includes a footer switch for each test circuit.

4. The apparatus of claim 1 further comprising source measurement unit force and sense pads for each source management unit utilized in test equipment.

5. The apparatus of claim 1 further comprising a digital select pad to receive a control signal for the selection circuitry operating to enable voltage control at the single test circuit while disabling all other test circuits.
